(19) United States
(12) Patent Application Publication
(10) Pub. No.: US 2026/0251157 A1
(43) Pub. Date: Aug. 27, 2026

(54) CONNECTION BRACKET FOR HEAT SINK, HEAT SINK, AND SERVER HEAT-DISSIPATION SYSTEM

(71) Applicant: Lenovo Global Technology (Taiwan) Limited., Taipei (TW)

(72) Inventors: Chao Yang HUANG, Taipei (TW); Jui-Chan FAN, Taipei (TW); PENG-KUEI WANG, Taipei (TW); Yu Han CHEN, Taipei (TW)

(21) Appl. No.: 19/538,340

(22) Filed: Feb. 12, 2026

(30) Foreign Application Priority Data
Feb. 26, 2025 (CN) 202510218442.1

(51) Int. Cl. F04D 29/60; H05K 7/20

(52) U.S. Cl. CPC F04D 29/601; H05K 7/2039; H05K 7/20418; H05K 7/20509

(57) ABSTRACT

A connection bracket includes a fixation device configured to connect a server motherboard to a bottom of the connection bracket, and a recess formed at a center of a top of the connection bracket and configured to be detachably connected to a bottom component of a heat sink. The recess has an accommodation space configured to accommodate the bottom component of the heat sink, so that the bottom component of the heat sink is rotatable around a center of the recess in the accommodation space to change a positional relationship between heat dissipation fins on two sides of the heat sink and memory modules on two sides of the server motherboard.

### CROSS-REFERENCE TO RELATED APPLICATION

This application claims priority to Chinese Patent Application No. 202510218442.1, filed on Feb. 26, 2025, the entire content of which is incorporated herein by reference.

### TECHNICAL FIELD

The present disclosure generally relates to the server heat dissipation technology field and, more particularly, to a connection bracket for a heat sink, a heat sink, and a server heat-dissipation system.

### BACKGROUND

Servers and heat sinks are generally fixed by welding. This makes it difficult to adjust the positional relationship between the server and the heat sink. In some circumstances, the heat sink needs to be forcibly removed.

For example, when the memory modules on two sides of the server need to be replaced or repaired, due to the heat sink occupying the space above the memory modules, operation is impossible, and the heat sink usually needs to be forcibly removed. Therefore, the disassembly and reassembly process is labor-intensive and complex.

### SUMMARY

In accordance with the disclosure, there is provided a connection bracket including a fixation device configured to connect a server motherboard to a bottom of the connection bracket, and a recess formed at a center of a top of the connection bracket and configured to be detachably connected to a bottom component of a heat sink. The recess has an accommodation space configured to accommodate the bottom component of the heat sink, so that the bottom component of the heat sink is rotatable around a center of the recess in the accommodation space to change a positional relationship between heat dissipation fins on two sides of the heat sink and memory modules on two sides of the server motherboard.

Also in accordance with the disclosure, there is provided a heat sink including heat dissipation fins on two sides of the heat sink, and a bottom component. A structure of the bottom component enables the bottom component to be embedded in a recess of a connection bracket to form a detachable connection with the connection bracket, and the bottom component is configured to rotate around a center of the recess in an accommodation space of the recess to change a positional relationship between the heat dissipation fins and memory modules on two sides of a server motherboard.

Also in accordance with the disclosure, there is provided a server heat-dissipation system including a server, a heat sink, and a connection bracket. The server includes memories on two sides of the server. The connection bracket includes a fixation device connecting the server to a bottom of the connection bracket, and a recess formed at a center of a top of the connection bracket and having an accommodation space. The heat sink includes heat dissipation fins on two sides of the heat sink, and a bottom component. A structure of the bottom component enables the bottom component to be embedded in the recess of the connection bracket to form a detachable connection with the connection bracket, and the bottom component is configured to rotate around a center of the recess in the accommodation space of the recess to change a positional relationship between the heat dissipation fins and the memories to be a first positional relationship or a second positional relationship. In the first positional relationship, the memories are located right below the heat dissipation fins. In the second positional relationship, a space below the heat dissipation fins is empty and a space right above the memories is empty.

### BRIEF DESCRIPTION OF THE DRAWINGS

FIG. 1 is a schematic structural diagram of a server heat-dissipation system.

FIG. 2 is a schematic structural diagram of a connection bracket for a heat sink consistent with the present disclosure.

FIG. 3 is a schematic structural diagram of another connection bracket for a heat sink consistent with the present disclosure.

FIG. 4 is a schematic structural diagram of another connection bracket for a heat sink consistent with the present disclosure.

FIG. 5 is a schematic structural diagram of another connection bracket for a heat sink consistent with the present disclosure.

FIG. 6 is a schematic structural diagram of a heat sink consistent with the present disclosure.

FIG. 7 is a schematic structural diagram of another heat sink consistent with the present disclosure.

FIG. 8 is a schematic structural diagram of another heat sink consistent with the present disclosure.

FIG. 9 is a schematic structural diagram of another server heat-dissipation system consistent with the present disclosure.

FIG. 10 is a schematic structural diagram of another server heat-dissipation system consistent with the present disclosure.

FIG. 11 is a schematic flowchart of a process of using the connection bracket consistent with the present disclosure.

FIG. 12 is a schematic structural diagram of a heat dissipation system in various states consistent with the present disclosure.

FIG. 13 is a schematic structural diagram of a connection bracket consistent with the present disclosure.

FIG. 14 is a schematic structural diagram showing deployment positions of the spring screws in the connection bracket consistent with the present disclosure.

FIG. 15 is a schematic structural diagram of a groove structure on the base consistent with the present disclosure.

FIG. 16 schematically shows the connection bracket and the connection bracket and heat sink in an initial position of the operating state consistent with the present disclosure.

FIG. 17 schematically shows the connection bracket and the connection bracket and heat sink in a rotated position of the service state consistent with the present disclosure.

FIG. 18 schematically shows different types of heat sinks consistent with the present disclosure.

### DETAILED DESCRIPTION OF THE EMBODIMENTS

To make the objectives, technical solutions, and advantages of the embodiments of the present disclosure clearer, the specific technical solutions of the present disclosure will be further described in detail below with reference to the accompanying drawings in the embodiments of the present disclosure. The following embodiments are used to illustrate the present disclosure, but are not intended to limit the scope of the present disclosure.

The following descriptions associated with “some embodiments” describes a subset of all possible embodiments. However, it is understood that “some embodiments” may be the same or different subsets of all possible embodiments and can be combined with each other without conflict.

In the following description, the terms associated with “first/second/third” are used merely to distinguish different objects and do not represent a specific order of the objects, nor do they imply any sequential limitation. It is understood that “first/second/third” can be interchanged in specific order or sequence where permitted, so that the embodiments of the present disclosure described herein can be implemented in an order other than that illustrated or described herein.

Unless otherwise described, all technical and scientific terms used herein have the same meaning as commonly understood by one of ordinary skill in the art to which the present disclosure pertains. The terminology used herein is merely for the purpose of describing embodiments of the present disclosure and is not intended to limit the present disclosure.

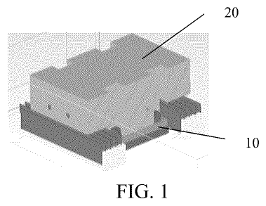

FIG. 1 shows a server heat-dissipation system including: a server 10 and a heat sink 20. The server 10 is welded and fixed to the heat sink 20. The server 10 is located at the bottom of the heat sink 20.

The connection method of the server 10 to the heat sink 20 can be seen in FIG. 1. The memory modules on two sides of the server 10 (also referred to as a “server motherboard”) is aligned with the heat dissipation fins on two sides of the heat sink 20. That is, the space above the memory modules on two sides of the server 10 is occupied by the heat dissipation fins on two sides of the heat sink 20.

It can be seen that if the memory modules on two sides of the server 10 needs to be repaired or replaced, the heat sink 20 needs be removed first to free up space for repair or replacement of the memory. However, since the server 10 and the heat sink 20 are welded together, the disassembly and assembly of the heat sink 10 is labor-intensive and complex.

The present disclosure provides a connection bracket for a heat sink, a heat sink, and a server heat-dissipation system. Embodiments of the connection bracket for a heat sink, the heat sink, and the server heat-dissipation system are described below.

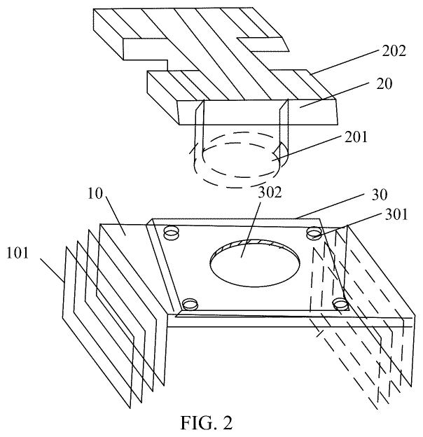

As shown in FIG. 2, the server motherboard 10 is fixedly connected to the bottom of a connection bracket 30 through a first fixation device 301.

A recess 302 is provided at a center of the top of the connection bracket 30, and the recess 302 is used for detachable connection with a bottom component 201 of the heat sink 20.

The recess 302 has a first space (also referred to as an “accommodation space”), which is configured to accommodate the bottom component 201 of the heat sink 20, so that the bottom component 201 of the heat sink 20 can be rotated around the center of the recess 302 in the first space, changing the positional relationship between the heat dissipation fins 202 on two sides of the heat sink 20 and the memory modules 101 on two sides of the server motherboard 10.

The connection bracket 30 is configured to connect the server 10 and the heat sink 20. After the connection is established, the server 10 is located at the bottom of the connection bracket, and the heat sink 20 is located at the top of the connection bracket. The present disclosure does not limit the outer shape of the connection bracket, which can be configured according to actual needs. For example, the outer shape of the connection bracket 30 can be rectangular, elliptical, etc.

For example, the connection bracket 30 can be a rectangular structure having a thickness.

The present disclosure does not limit the material of the connection bracket 30, which can be configured according to actual needs. In some embodiments, the connection bracket 30 can be made of a material with good heat dissipation. For example, the connection bracket 30 can be made of pure copper, steel pipe, cast iron, copper-aluminum composite, die-cast aluminum, steel plate, etc. Of course, the connection bracket 30 can also be made of other materials, which are not listed here.

The first fixation device 301 is configured to fix the server motherboard 10. The present disclosure does not limit the specific structure of the first fixation device 301, which can be configured according to actual needs.

In some embodiments, the first fixation device can be a non-removable fixation device. For example, the first fixation device can be a weld connection, etc.

In some embodiments, the first fixation device is a removable fixation device. For example, the first fixation device 301 can be a screw fixation device. The removable fixation device can meet the needs of disassembly and assembly.

The present disclosure does not limit the position of the first fixation device 301 on the connection bracket, which can be configured according to actual needs.

In some embodiments, if the first fixation device 301 is a screw, and the outer shape of the connection bracket 30 is rectangular, then the first fixation device 301 can be positioned at one of the four corners of the rectangle.

A recess 302 is provided at the center of the top of the connection bracket 30, and the recess 302 is used for detachably connecting with the bottom component 201 of the heat sink 20.

The position of the recess 302 can be configured according to actual needs. In some embodiments, the recess 302 can be located at the center of the connection bracket 30. The recess 302 is detachably connected to the bottom component 201 of the heat sink 20. The present disclosure does not limit the shape of the recess 302, which can be configured according to the bottom component 201 of the heat sink 20.

In some embodiments, both the recess 302 and the bottom component 201 of the heat sink 20 are cylindrical. Specifically, the cylindrical inner diameter of the recess 302 is slightly greater than the cylindrical diameter of the bottom component 201 of the heat sink 20, so that the bottom component 201 of the heat sink 20 can be embedded in the cylindrical space of the recess 302.

Of course, the recess 302 and the bottom component 201 of the heat sink 20 can also have other shapes, which are not listed here.

The present disclosure does not limit the depth of the recess 302, which can be configured according to the depth of the bottom component 201 and actual needs.

The recess 302 has a first space, which is configured to accommodate the bottom component 201 of the heat sink 20, so that the bottom component 201 of the heat sink 20 can be rotated around the center of the recess 302 in the first space, thereby changing the positional relationship between the heat dissipation fins 202 on two sides of the heat sink 20 and the memory modules 101 on two sides of the server motherboard 10.

It should be noted that during the rotation, the heat sink 20 rotates around the center of the recess 302. During rotation, the heat sink 20 rotates, while the connection bracket 30 and the server 10 remain stationary, thereby changing the positional relationship between the heat dissipation fins 202 on two sides of the heat sink 20 and the memory modules 101 on two sides of the server motherboard 10.

The present disclosure does not limit the angle of rotation or the positional relationship between the heat dissipation fins 202 on two sides of the heat sink 20 and the memory modules 101 on two sides of the server motherboard 10, which can be configured according to actual needs.

For example, in normal operation, the heat sink 20 is rotated in a first direction so that the heat dissipation fins 202 on two sides of the heat sink 20 are located directly above the memory modules 101 on two sides of the server motherboard 10, thereby improving the heat dissipation performance. When maintenance or replacement of the memory modules 101 is needed, the heat sink 20 is rotated in a second direction so that the heat dissipation fins 202 on two sides of the heat sink 20 are offset from the space directly above the memory modules 101 on two sides of the server motherboard 10, freeing up the space directly above the memory modules 101 for maintenance and replacement.

The present disclosure also does not limit the direction of rotation, which can be configured according to actual needs. For example, the first direction can be clockwise, and the second direction can be counterclockwise. Of course, the first direction can also be counterclockwise, and the second direction can be clockwise.

The present disclosure provides a connection bracket for a heat sink. The connection bracket fixes the server motherboard to the bottom of the connection bracket via a first fixation device. A recess is provided at the center of the top of the connection bracket. The recess is used for detachable connection with the bottom component of the heat sink, where, the recess has a first space, and the first space is configured to accommodate the bottom component of the heat sink, so that the bottom component of the heat sink can be rotated around the center of the recess in the first space, changing the positional relationship between the heat dissipation fins on two sides of the heat sink and the memory modules on two sides of the server motherboard.

In this way, by rotating the heat sink, the bottom component of the heat sink can be rotated around the center of the recess in the first space, thereby the heat dissipation fins of the heat sink can be rotated, thus changing the positional relationship between the heat dissipation fins 202 on two sides of the heat sink 20 and the memory modules 101 on two sides of the server motherboard 10. In this structure, the positional relationship between the heat dissipation fins 202 and the memory modules 101 is not fixed, but can be rotated. This design allows for changing the positional relationship between the heat dissipation fins and the memory modules by rotation. This enables adjustment of the positional relationship between the heat dissipation fins and the memory modules according to various practical scenarios, achieving flexibility, convenience, and simple implementation, without affecting the original heat dissipation performance.

Next, the structure of the recess 302 will be described.

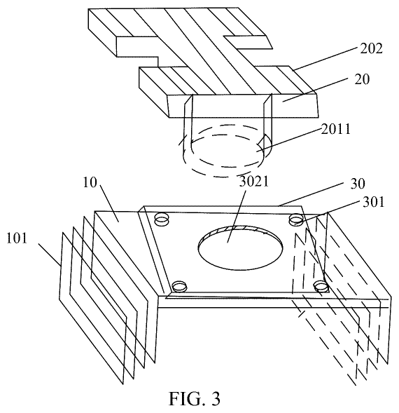

In some embodiments, as shown in FIG. 3, when the bottom component 201 of the heat sink 20 includes a cylindrical component 2011, since the bottom component 201 needs to be detachably connected to the recess 302, the recess 302 includes a cylindrical recess 3021 with a radius of a first radius.

The cylindrical recess 3021 has a cylindrical space, which can form an embedded fit with the cylindrical component 2011 of the bottom component 201 of the heat sink 20, which has a radius of the first radius.

The present disclosure does not limit the size of the first radius, which can be configured according to actual needs. The first radius is an inner diameter for the cylindrical recess 3021, and the first radius is an outer diameter for the cylindrical component of the bottom component 201 of the heat sink 20.

The present disclosure does not limit the depth of the cylindrical recess 3021 or the height of the cylindrical component 2011 of the bottom component 201 of the heat sink 20, and these can be configured according to actual needs.

In some embodiments, the height of the cylindrical component 2011 is greater than or equal to the depth of the cylindrical recess 3021.

It can be seen that the recess 302 is cylindrical recess 3021, and the bottom component 201 of the heat sink 20 is cylindrical component 2011. The contact area between the recess 302 and the bottom component 201 of the heat sink 20 is circular, thus providing rotational space, and the remaining space is small. Due to the poor thermal conductivity of air, this structure offers good sealing and good thermal conductivity while enabling rotational movement.

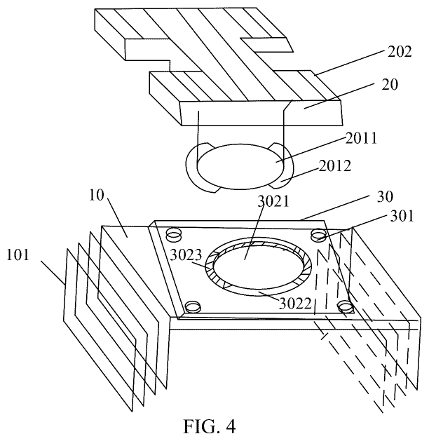

In some embodiments, as shown in FIG. 4, when the bottom component 201 of the heat sink 20 includes a cylindrical component 2011 and a fan-shaped columnar component 2012, since the bottom component 201 needs to be detachably connected to the recess 302, the recess 302 includes a cylindrical recess 3021 with a radius equal to the first radius. The cylindrical recess 3021 has a cylindrical space that can form an embedded fit with the cylindrical component 2011 of the bottom component 201 of the heat sink 20, which also has a radius equal to the first radius.

The recess 302 also includes fan-shaped columnar recesses 3022 that are spaced apart circumferentially along the periphery of the cylindrical recess 3021. The fan-shaped columnar recesses 3022 have a fan-shaped columnar space for accommodating the fan-shaped columnar component 2012 of the bottom component 201 of the heat sink 20.

The connection bracket 30 also includes fan-shaped columnar hollow parts 3023 that are spaced apart circumferentially along the periphery of the cylindrical recess 3021. A fan-shaped columnar gap is formed between the fan-shaped columnar hollow parts 3023 and the bottom surface of the connection bracket 30, and the fan-shaped columnar gap is configured to accommodate the fan-shaped columnar component in the bottom component of the heat sink.

The present disclosure does not limit the numbers of fan-shaped columnar recesses 3022 and fan-shaped columnar hollow parts 3023, which can be configured according to actual needs. For example, one fan-shaped columnar recess 3022 and one fan-shaped columnar hollow parts 3023 can be arranged circumferentially along the periphery of the recess 302. For example, multiple fan-shaped columnar recesses 3022 and multiple fan-shaped columnar hollow parts 3023 can be arranged circumferentially along the periphery of the recess 302.

The fan-shaped columnar hollow parts 3023, the fan-shaped columnar recesses 3022, and the cylindrical recess 3021 share the same center. The fan-shaped columnar components 2012 and the cylindrical component 2011 also share the same center. This center is the center around which rotation occurs.

The fan-shaped columnar hollow parts 3023 and the fan-shaped columnar recesses 3022 are arranged alternatively along the circumference of the cylindrical recess 3021. The fan-shaped columnar structures of the fan-shaped columnar hollow parts 3023 and the fan-shaped columnar recesses 3022 are consistent, and are also consistent with the fan-shaped columnar structure of the fan-shaped columnar component 2012.

Both the fan-shaped columnar gap and the fan-shaped columnar recess 3022 can be used to accommodate the fan-shaped columnar component 2012.

In some embodiments, in the maintenance state of the server, the fan-shaped columnar component 2012 is rotated within the fan-shaped columnar gap. The fan-shaped columnar gap prevents the fan-shaped columnar component 2012 from falling off or moving, then the heat sink 20 and the connection bracket 30 remain connected and do not separate, so that after maintenance, the fan-shaped columnar component 2012 can be accurately rotated into the space of the fan-shaped columnar recess 3022.

Consistent with the present disclosure, when the heat sink 20 is being rotated, the cylindrical component 2011 and the fan-shaped columnar component 2012 are rotated simultaneously around the center of the recess 302. The present disclosure not only allows for changing the positional relationship between the heat dissipation fins 202 on two sides of the heat sink 20 and the memory modules 101 on two sides of the server motherboard 10 by rotating the heat sink 20, but also prevents the fan-shaped columnar component 2012 from falling off or moving, ensuring that the heat sink 20 and the connection bracket 30 remain connected and do not separate, thereby improving the reliability of the connection between the connection bracket and the heat sink.

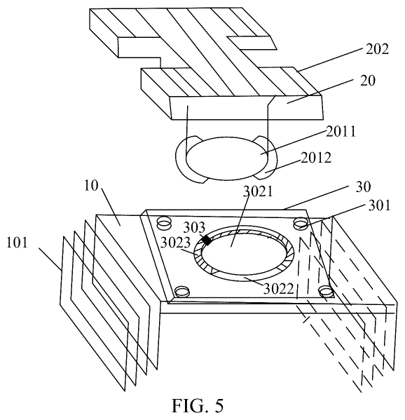

In some embodiments, as shown in FIG. 5, the recess 302 includes a cylindrical recess 3021 with a radius of a first radius. The cylindrical recess 3021 has a cylindrical space that can form an embedded fit with the cylindrical component 2011 of the bottom component 201 of the heat sink 20, which also has a radius of the first radius.

The recess 302 also includes fan-shaped columnar recesses 3022 that are spaced apart circumferentially along the periphery of the cylindrical recess 3021. The fan-shaped columnar recess 3022 has a fan-shaped columnar space for accommodating the fan-shaped columnar component 2012 of the bottom component 201 of the heat sink 20.

The connection bracket 30 also includes fan-shaped columnar hollow parts 3023 that are spaced apart circumferentially along the periphery of the cylindrical recess 3021. A fan-shaped columnar gap is formed between the fan-shaped columnar hollow parts 3023 and the bottom surface of the connection bracket 30, the fan-shaped columnar gap being used to accommodate the fan-shaped columnar component of the bottom component of the heat sink.

The connection bracket 30 also includes a cutoff planar part 303, the cutoff planar part 303 being located at a first position between the fan-shaped columnar recess 3022 and the fan-shaped columnar hollow part 3023.

The cutoff planar part 303 is a fan-shaped columnar solid part, and the connection bracket 30 separates the space between a fan-shaped columnar space and a fan-shaped columnar gap through the fan-shaped columnar solid part.

The cutoff planar part 303 is configured to: after the bottom component 201 of the heat sink 20 is rotated around the center of the recess 302 in the first space to a first angle (also referred to as a “stop angle”), prevent the bottom component of the heat sink from continuing to rotate, thereby changing the positional relationship between the heat dissipation fins 202 on two sides of the heat sink 20 and the memory modules 101 on two sides of the server motherboard 10.

The present disclosure does not limit the value of the first angle, which can be determined according to actual needs. For example, to maximize the space utilization of the memory modules 101, the first angle can be set to 90°.

The cutoff planar part 303 is located at a first position between the fan-shaped columnar recess 3022 and the fan-shaped columnar hollow parts 3023. Since both the fan-shaped columnar recess 3022 and the fan-shaped columnar hollow parts 3023 have space to accommodate the fan-shaped columnar component 2012, the heat sink 20 can be rotated in the recess 302. To limit the rotation angle, the cutoff planar part 303 is provided at the first position between the fan-shaped columnar recess 3022 and the fan-shaped columnar hollow parts 3023. Since the cutoff planar part 303 is a fan-shaped columnar solid part, it can prevent the bottom component of the heat sink from continuing to rotate, thereby changing the positional relationship between the heat dissipation fins 202 on two sides of the heat sink 20 and the memory modules 101 on two sides of the server motherboard 10.

The present disclosure does not limit the position where the cutoff planar part 303 is located, which can be configured according to the first angle of rotation as needed.

For example, when the first angle is 90°, and the fan-shaped columnar recess 3022 and the fan-shaped columnar hollow parts 3023 are quarter-circle fan-shaped columnar arc arranged at intervals, the cutoff planar part 303 can be arranged at a position between the fan-shaped columnar recess 3022 and the fan-shaped columnar hollow parts 3023, thereby achieving a 90° rotation first angle.

Consistent with the present disclosure, the connection bracket not only allows for the rotation of the heat sink but also enables precise control of the rotation angle, thereby maximizing the space above the memory modules 101.

In some embodiments, the connection bracket 30 also includes a first threaded hole and a second threaded hole located on two sides of the recess 302.

The connection bracket 302 is fixedly connected to the heat sink 20 through the first threaded hole and the second threaded hole.

The present disclosure does not limit the position and diameter of the first threaded hole and the second threaded hole, which can be configured according to actual needs.

Specifically, before the server starts operating, the connection bracket 302 is fixedly connected to the heat sink 20 through the first threaded hole and the second threaded hole, thereby strengthening the fixation of the heat sink and preventing the heat sink from moving, which would affect the heat dissipation performance. When the memory 101 needs to be repaired or replaced, the fixed connection between the first threaded hole and the second threaded hole and the heat sink 20 is loosened, and the heat sink 20 is rotated to change the positional relationship between the heat dissipation fins 202 on two sides of the heat sink 20 and the memory modules 101 on two sides of the server motherboard 10, freeing up the space above the memory 101 for easy repair and replacement.

In some embodiments, the connection bracket 30 also includes a first thermal conductive lubrication material.

The first thermal conductive lubrication material is filled into the remaining space in the first space after the recess 302 contacts the bottom component 201 of the heat sink 20.

In practical application, there may be errors in the structural design, and it may not be possible to achieve a seamless connection between the recess 302 and the bottom component 201 of the heat sink 20. Therefore, there may be remaining space in the first space after the recess 302 contacts the bottom component 201 of the heat sink 20. If this remaining space is not filled with liquid, it is equivalent to being filled with air. Since air has poor thermal conductivity, the first thermal conductive lubrication material can be filled into the remaining space. This can improve heat dissipation performance and also provide lubrication, enabling a smooth rotation.

The present disclosure does not limit the material of the first thermal conductive lubrication material, which can be configured according to actual needs.

In some embodiments, the first thermal conductive lubrication material can be a blue thermal composite material.

After the heat sink is dissembled, the first thermal conductive lubrication material needs to be replaced to improve sealing. Consistent with the present disclosure, since the heat sink remains in contact with the connection bracket during rotation and there is no substantial separation, i.e., no air enters, the first thermal conductive lubrication material does not need to be replaced before and after rotation. The first thermal conductive lubrication material only needs to be replaced when its usage time exceeds the reference usage time specified in the instruction manual, in order to ensure effective heat dissipation.

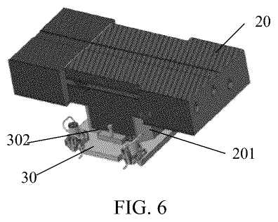

FIG. 6 schematically shows a heat sink 20 consistent with the disclosure. As shown in FIG. 6, the bottom component 201 of the heat sink 20 has a first structure. The bottom component 201 with the first structure can be embedded into the recess 302 of the connection bracket 30, forming a detachable connection with the connection bracket 30.

The bottom component 201 of the heat sink 20 is configured to rotate around the center of the recess 302 in the first space of the recess 302, changing the positional relationship between the heat dissipation fins 202 on two sides of the heat sink 20 and the memory modules on two sides of the server motherboard.

The present disclosure does not limit the first structure of the bottom component 201 of the heat sink 20, which can be configured according to actual needs. The first structure can be embedded into the recess 302 of the connection bracket 30, forming a detachable connection with the connection bracket 30. The first structure of the bottom component 201 corresponds to the structure of the recess 302 of the connection bracket 30. If the structure of the recess 302 is a cylindrical recess structure, then the first structure of the bottom component 201 is a cylindrical component. Of course, the first structure can also be a cylindrical structure with a fan-shaped columnar structure, etc., which will not be listed here.

For the heat sink 20, the present disclosure only describes the first structure of the bottom component 201 of the heat sink 20. The present disclosure does not limit the structure of top of the heat sink 20, which can be configured according to actual needs. Since the difference between different types of heat sinks lies in the different arrangement structures of the heat dissipation fins at the top of the heat sink, the heat sink 20 here can be various types of heat sinks with a bottom component having the first structure. For example, the heat sink 20 can be a 1U wing-shaped sink, a 2U wing-shaped sink, an H-wing-shaped sink, an S-wing-shaped sink, etc.

For the heat sink provided in the present disclosure, since the bottom component of the heat sink has a first structure, the bottom component with the first structure can be embedded into the recess of the connection bracket using the first structure, forming a detachable connection with the connection bracket. In this way, the heat sink can be rotated around the center of the recess, thereby changing the positional relationship between the heat dissipation fins on two sides of the heat sink and the memory modules on two sides of the server motherboard. This achieves flexibility, convenience, and simple implementation, and does not affect the original heat dissipation performance. Further, this heat sink is compatible with various types of heat dissipation fins, offering strong compatibility and a wide range of applications.

The structure of the bottom component 201 of the heat sink 20 is described below.

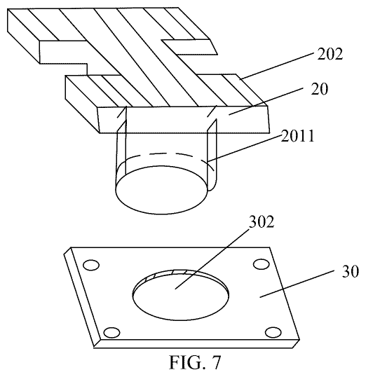

In some embodiments, as shown in FIG. 7, the bottom component 201 of the heat sink 20 includes a cylindrical component 2011 with a first radius, and the cylindrical component 2011 can be embedded into the cylindrical space of the recess 302 of the connection bracket 30.

The present disclosure does not limit the length of the first radius or the height of the cylindrical component 2011, which can be configured according to the recess 302 of the connection bracket 30.

Consistent with the present disclosure, the bottom component 201 of the heat sink 20 is a cylindrical component 2011. Since the cylindrical component is easy to be rotated, the structure of the bottom component of this heat sink is simple and practical.

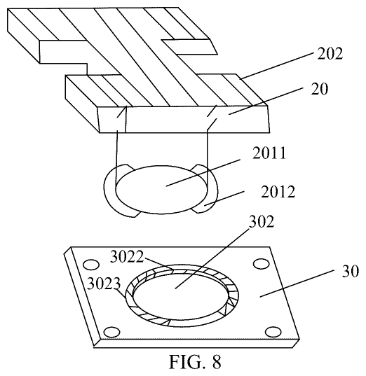

In some embodiments, as shown in FIG. 8, the bottom component 201 of the heat sink 20 includes: a cylindrical component 2011 with a first radius; and fan-shaped columnar components 2012 that are spaced apart circumferentially along the periphery of the cylindrical component 2011.

The cylindrical component 2011 can be embedded into the cylindrical space of the recess 302 of the connection bracket 30. The fan-shaped columnar components 2012 can be embedded into the fan-shaped columnar space of the fan-shaped columnar recess 3022 of the connection bracket 30, or, the fan-shaped columnar components 2012 can be embedded into the fan-shaped columnar gap of the fan-shaped columnar hollow parts 3023 of the connection bracket 30.

The present disclosure does not limit the number of spaced-apart fan-shaped columnar component 2012, and the number can be configured according to the numbers of fan-shaped columnar recesses 3022 and fan-shaped columnar hollow parts 3023 of the connection bracket 30. For example, if the numbers of both fan-shaped columnar recesses 3022 and fan-shaped columnar hollow parts 3023 of the connection bracket 30 are 2, then the number of fan-shaped columnar component 2012 is also 2.

Consistent with the present disclosure, the bottom component of the heat sink can also include fan-shaped columnar component, so that the fan-shaped columnar component can be rotated and be embedded into the fan-shaped columnar hollow parts 3023 of the connection bracket 30 after contacting the fan-shaped columnar recesses 3022 of the connection bracket. This prevents the fan-shaped columnar component 2012 from falling off or moving, ensuring that the heat sink 20 and the connection bracket 30 remain connected, thereby improving the reliability of the connection between the connection bracket and the heat sink.

In a third aspect, the present disclosure example provides a server heat-dissipation system. The server uses a heat sink including a connection bracket for heat dissipation. The connection bracket is the connection bracket 30 provided in the first aspect, and the heat sink is the heat sink 20 provided in the second aspect.

It should be noted that the structure of the connection bracket 30 corresponds to the structure of the heat sink 20.

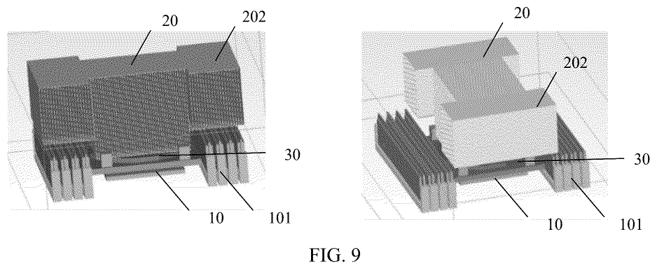

As shown in FIG. 9, in this heat dissipation system, the top of the connection bracket 30 is connected to the heat sink 20, the bottom of the connection bracket 30 is connected to the server motherboard 10, the heat dissipation fins 202 on two sides of the heat sink 20 have a first positional relationship or a second positional relationship with the memory modules 101 on two sides of the server motherboard 10.

In the first positional relationship, the space right below the heat dissipation fins 202 on two sides of the heat sink 20 is occupied by the memory modules 101 on two sides of the server motherboard 10.

For the first positional relationship, the space right below the heat dissipation fins 202 on two sides of the heat sink 20 being occupied by the memory modules 101 on two sides of the server motherboard 10 can maximize the heat dissipation performance.

In the second positional relationship, the space right below the heat dissipation fins 202 on two sides of the heat sink 20 is empty (i.e., not occupied), and the space right above the memory modules 101 on two sides of the server motherboard 10 is also empty (i.e., not occupied).

Regarding the second positional relationship, the space right above the memory modules 101 on two sides of the server motherboard 10 is empty, allowing for convenient replacement or repair of the memory modules.

Of course, other positional relationships are also possible, such as intermediate states during rotation, where a part of the space right above the memory modules 101 is empty, and another part is occupied by heat dissipation fins, etc., which will not be described in detail here.

Consistent with the present disclosure, for the server heat-dissipation system, the heat sink and the server can be connected through a connection bracket. The positional relationship between the heat dissipation fins 202 on two sides of the heat sink 20 and the memory modules 101 on two sides of the server motherboard 10 can be changed by rotating the heat sink. When the server is operating, the heat sink is rotated to achieve the first positional relationship between the heat dissipation fins 202 and the memory modules 101 to maximize the heat dissipation performance. When the memory module needs to be repaired, the heat sink is rotated to achieve the second positional relationship between the heat dissipation fins 202 and the memory modules 101, freeing up the space above the memory for easy repair and replacement.

The server heat-dissipation system will be described below using a 2U wing-shaped sink as an example.

High-power processors in 2U systems require higher-performance 2U wing-shaped CPU heat sinks. The heat sink usually occupies the space right above the memory modules to allow for more fin surface area for heat dissipation. When replacing or removing memory (the memory modules on two sides of the server mentioned above) for repair, the 2U wing-shaped sink occupies the top pace of the memory, making memory removal more difficult.

It can be seen that the space right above the memory modules will cause difficulties and inconvenience in repairing and replacing memory modules. Currently, the CPU heat sink needs to be removed, as well as the memory, and additional thermal interface material (TIM) is needed for the disassembly and assembly process.

Consistent with the present disclosure, one part of the wing-shaped sink has a circular base with welded heat pipes and wing-shaped fins, another part is a square base with a circular groove and spring screws for assembly with the CPU processor. The two parts are connected to each other with lubricant and secured with a clamp.

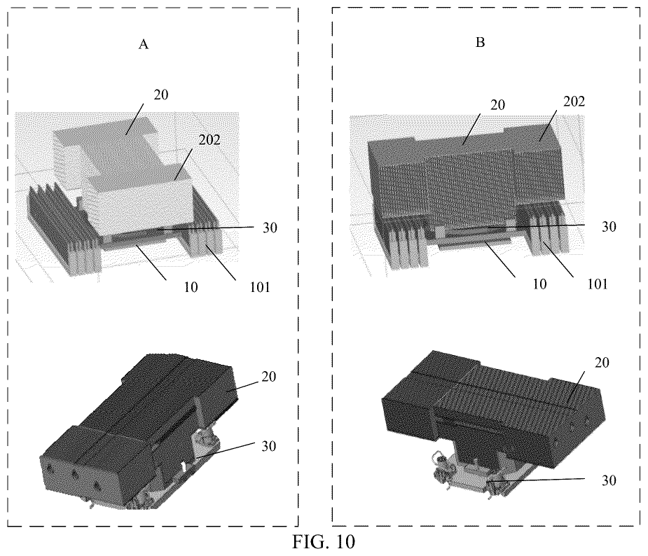

When memory module needs to be repaired or replaced, the clamp can be loosened and the wing-shaped sink can be rotated 90°, freeing up the space right above the memory, as shown in part A of FIG. 10, allowing the memory to be replaced without removing the CPU heat sink. After replacement, the wing-shaped sink is rotated back to its original position and secured for normal operation, as shown in part B of FIG. 10. The lubricant is filled into the gaps and prevents air from entering to affect heat dissipation performance.

FIG. 10 shows a server 10, a heat sink 20, and a connection bracket 30.

Consistent with the present disclosure, the circular base with fins can be rotated to clear the space right above the memory, simplifying maintenance. Since the CPU heat sink does not need to be removed for memory replacement, and the fins remain in contact with the base during the heat dissipation fin rotation process, no dust will accumulate on the contact surface to affect heat sink performance. If the lubricant is still within its expiration date, there is no need to apply additional TIM material. This structure can be applied to different heat sinks with different fin types to meet different configuration requirements.

The following describes the process of using the connection bracket.

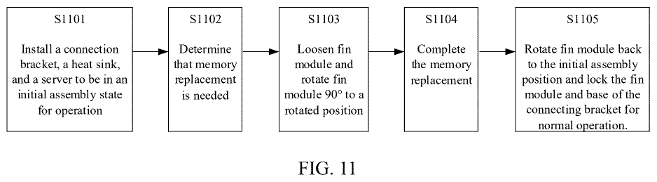

As shown in FIG. 11, the process includes, but is not limited to, S1101 to S1105 below.
At S1101, a connection bracket, a heat sink, and a server are installed to be in an initial assembly state for operation.

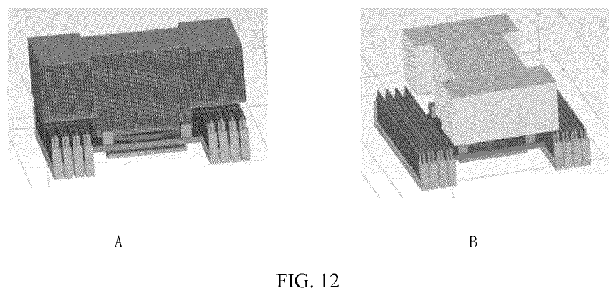

FIG. 12A can be referenced to for the initial assembly state.
At S1102, it is determined that memory replacement is needed.
At S1103, the fin module (of the heat sink) is loosened and rotated 90° to a rotated position.

FIG. 12B can be referenced to for the state of the rotated position.
At S1104, the memory replacement is completed.
At S1105, the fin module is rotated back to the initial assembly position and the fin module and the base (of the connection bracket) are locked for normal operation.

The structure of the connection bracket is described below.

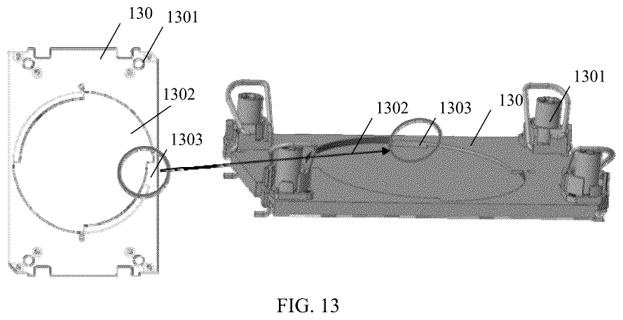

As shown in FIG. 13, the connection bracket 130 includes: a spring screw 1301, a groove structure 1302 on a base, and a cutoff part 1303 at the end of the groove structure.

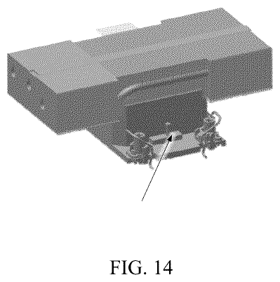

The spring screw can be deployed at the position indicated by the arrow in FIG. 14. The spring screw is configured to fix the wing-shaped sink to the base of the connection bracket.

The groove structure on the base of the connection bracket ensures that the heat sink does not separate from the base of the connection bracket during rotation.

During assembly, the base of the heat sink is inserted into the connection bracket first. The base has two wings. Then, the base of the heat sink is rotated to guide the wings into a gap of the connection bracket, preventing the heat sink from separating from the connection bracket. A solid part of the connection bracket limits the rotation to stop after being rotated 90°.

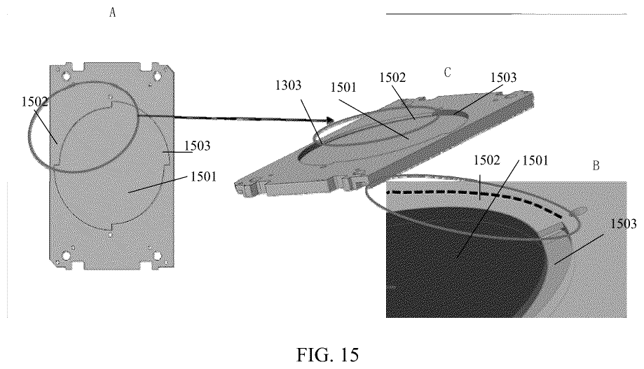

The groove structure on the base of the connection bracket is shown in FIG. 15.

The plan view of the groove structure on the base of the connection bracket can be seen in part A of FIG. 15. In part A, the groove structure includes a central circular part 1501, a gap fin part 1502, and a hollow fin part 1503. The solid line represents the gap fin part 1502, and the hollow fin part 1503 is the same as the central circular part 1501.

As shown in part B of FIG. 15, the dashed line represents the gap fin part 1502.

As shown in part C of FIG. 15, the cutoff part 1303 at the end of the groove structure is located at the end of the gap fin part 1502 and is a solid part, positioned at the end of the groove structure to limit the heat sink to a 90° rotation position.

The various states during the rotation process are described below.

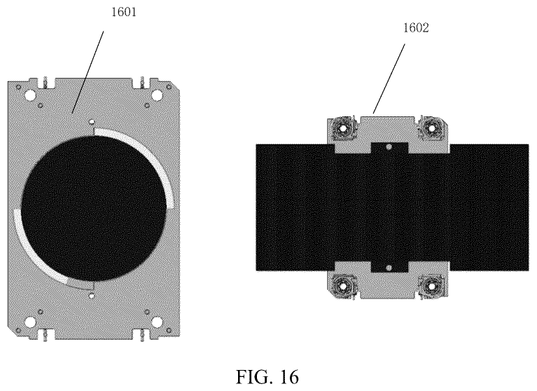

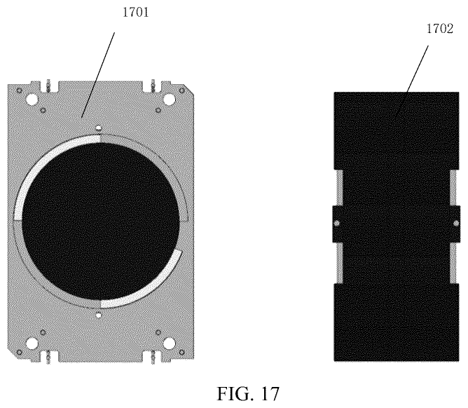

Refer to FIGS. 16 and 17. FIG. 16 shows the initial position of the operating state, where the left part 1601 in FIG. 16 is a schematic illustration of the connection bracket, and the right part 1602 in FIG. 16 is a schematic illustration of the connection bracket and the heat sink. FIG. 17 shows the rotated position in the maintenance state, where the left part 1701 in FIG. 17 is a schematic illustration of the connection bracket, and the right part 1702 in FIG. 17 is a schematic illustration of the connection bracket and the heat sink.

Tests were conducted on the use of various types of heat sinks.

Test conditions included: CPU power: 205 W; ambient temperature: 35° C.; airflow: 40 CFM.

Under these test conditions, the heat dissipation performance of the 2U wing-shaped sink system and the rotatable 2U wing-shaped sink system were tested. Among them, the 2U wing-shaped dissipation system is equivalent to a non-rotating conventional heat dissipation system, and the rotatable 2U wing-shaped dissipation system is equivalent to the rotatable heat dissipation system provided in the present disclosure.

The CPU temperatures for the 2U wing-shaped sink system and the rotatable 2U wing-shaped sink system are as follows: the CPU temperature in the 2U wing-shaped dissipation system is 75° C., and the CPU temperature in the rotatable 2U wing-shaped dissipation system is 76.4° C. The two are very close, indicating that there is no significant difference in the heat dissipation performance between the conventional wing-shaped dissipation system and the rotatable wing-shaped dissipation system. That is, the heat dissipation system provided in the present disclosure does not affect the heat dissipation performance of the heat sink.

Next, the additional feature of heat sinks with different fin types is described.

The fin type of the heat sink can be different according to different configuration requirements, and the base can be shared across all fin types to save base processing costs.

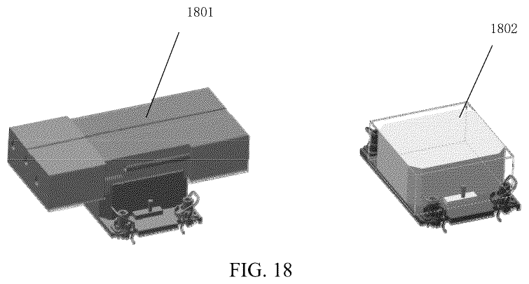

As shown in FIG. 18, the left side 1801 is a 2U heat sink configuration, and the right side 1802 is a 1U heat sink configuration.

It should be understood that the phrase “one embodiment” or “some embodiments” mentioned throughout the present disclosure means that a particular feature, structure, or characteristic related to the embodiment is included in at least one embodiment of the present disclosure. Therefore, the phrases “in one embodiment” or “in some embodiments” appearing throughout the disclosure do not necessarily refer to the same embodiment. Furthermore, these specific features, structures, or characteristics may be combined in any suitable manner in one or more embodiments. It should be understood that in various embodiments of the present disclosure, the numerical order of the above processes does not imply the order of execution, and the execution order of each process should be determined by its function and inherent logic, and should not constitute any limitation on the implementation process of the embodiments of the present disclosure. The above numbering of the embodiments of the present disclosure is for descriptive purposes only and does not represent the superiority or inferiority of the embodiments.

It should be noted that, in the present disclosure, the terms “comprise,” “include,” or any other variation thereof are intended to cover non-exclusive inclusion, so that a process, method, article, or apparatus that includes a series of elements not only includes those elements but also includes other elements not explicitly listed, or includes elements inherent to such a process, method, article, or apparatus. Without further limitations, an element associated with the phrase “comprising a . . . ” does not exclude the presence of other identical elements in the process, method, article, or apparatus that includes that element.

In the embodiments of the present disclosure, it should be understood that the disclosed devices and methods can be implemented in other ways. The embodiments of device described above are merely illustrative. For example, the division of the components is only a logical functional division, and other divisions are possible in actual implementation. For example, multiple units or components can be combined, or integrated into another system, or some features can be omitted or not implemented. In addition, the coupling, direct coupling, or communication connections between the various components shown or discussed can be through various interfaces, and the indirect coupling or communication connections between devices or units can be electrical, mechanical, or other forms.

The units described above as separate components may or may not be physically separate. The components shown as units may or may not be physical units; they can be located in one place or distributed across multiple network units; some or all of the units can be selected according to actual needs to achieve the purpose of the present disclosure.

Furthermore, in the embodiments of the present disclosure, all functional units can be integrated into one processing unit, or each unit can be a separate unit, or two or more units can be integrated into one unit; the above integrated units can be implemented in hardware form, or in the form of hardware plus software functional units.

Those skilled in the art will understand that all or part of the processes of the above method embodiments can be completed by hardware with program instructions. The aforementioned program can be stored in a computer-readable storage medium. When the program is executed, it performs the processes including the method described in the above embodiments; and the aforementioned storage medium includes various media that can store program code, such as mobile storage devices, read-only memory, magnetic disks, or optical discs.

If the integrated units of the present disclosure are implemented in the form of software functional modules and sold or used as independent products, they can also be stored in a computer-readable storage medium. Based on this, the technical solution of the embodiments of the present disclosure, in essence or in the part that contributes to the relevant technology, can be in the form of a software product. This computer software product is stored in a storage medium and includes several instructions to enable a computer device (which can be a personal computer, server, or network device, etc.) to perform all or part of the methods described in the embodiments of the present disclosure. The aforementioned storage media include various media capable of storing program code, such as mobile storage devices, magnetic disks, or optical discs.

The above description only illustrates embodiments of the present disclosure, but the scope of the present disclosure is not limited thereto. Any variations or substitutions that can be easily conceived by those skilled in the art within the technical scope disclosed in the present disclosure should be within the scope of the present disclosure. Therefore, the scope of the present disclosure should be consistent with the scope of the claims.

What is claimed is:

1. A connection bracket comprising:
a fixation device configured to connect a server motherboard to a bottom of the connection bracket; and
a recess formed at a center of a top of the connection bracket, the recess being configured to be detachably connected to a bottom component of a heat sink;
wherein the recess has an accommodation space configured to accommodate the bottom component of the heat sink, so that the bottom component of the heat sink is rotatable around a center of the recess in the accommodation space to change a positional relationship between heat dissipation fins on two sides of the heat sink and memory modules on two sides of the server motherboard.

2. The connection bracket according to claim 1, wherein:
the recess includes a cylindrical recess; and
the cylindrical recess has a cylindrical space configured to form an embedded fit with a cylindrical component of the bottom component of the heat sink.

3. The connection bracket according to claim 2, wherein:
the recess further includes fan-shaped columnar recesses that are spaced apart circumferentially along a periphery of the cylindrical recess; and
each of the fan-shaped columnar recess has a fan-shaped columnar space configured to accommodate a fan-shaped columnar component of the bottom component of the heat sink.

4. The connection bracket according to claim 3, wherein:
the connection bracket further includes fan-shaped columnar hollow parts that are spaced apart circumferentially along the periphery of the cylindrical recess; and
each of the fan-shaped columnar hollow parts forms a fan-shaped columnar gap with a bottom surface of the connection bracket, the fan-shaped columnar gap being configured to accommodate the fan-shaped columnar component of the bottom component of the heat sink.

5. The connection bracket according to claim 3, further comprising:
a cutoff planar part disposed between one fan-shaped columnar recess of the fan-shaped columnar recesses and one fan-shaped columnar hollow part of the fan-shaped columnar hollow parts;
the cutoff planar part is a fan-shaped columnar solid part and configured to separate a space between the fan-shaped columnar space of the one fan-shaped columnar recess and the fan-shaped columnar gap of the one fan-shaped columnar hollow part; and
the cutoff planar part is configured to prevent the bottom component of the heat sink from continuing to rotate after the bottom component of the heat sink is rotated to an angle in the accommodation space around the center of the recess.

6. The connection bracket according to claim 1, further comprising:
a first threaded hole and a second threaded hole disposed on two sides of the recess;
wherein the connection bracket is fixedly connected to the heat sink through the first threaded hole and the second threaded hole.

7. The connection bracket according to claim 1, further comprising:
a thermal conductive lubrication material configured to be filled in a remaining space of the accommodation space after the recess contacts the bottom component of the heat sink.

8. A heat sink comprising:
heat dissipation fins on two sides of the heat sink; and
a bottom component, a structure of the bottom component enabling the bottom component to be embedded in a recess of a connection bracket to form a detachable connection with the connection bracket, and the bottom component being configured to rotate around a center of the recess in an accommodation space of the recess to change a positional relationship between the heat dissipation fins and memory modules on two sides of a server motherboard.

9. The heat sink according to claim 8, wherein the bottom component includes a cylindrical component configured to be embedded in a cylindrical space of the recess of the connection bracket.

10. The heat sink according to claim 9, wherein:
the bottom component further includes fan-shaped columnar components that are spaced apart circumferentially along a periphery of the cylindrical component; and
the fan-shaped columnar components are configured to be embedded in fan-shaped columnar spaces of fan-shaped columnar recesses of the connection bracket.

11. The heat sink according to claim 9, wherein:
the bottom component further includes fan-shaped columnar components that are spaced apart circumferentially along a periphery of the cylindrical component; and
the fan-shaped columnar components are configured to be embedded in fan-shaped columnar gaps of fan-shaped columnar hollow parts of the connection bracket.

12. A server heat-dissipation system comprising:
a server including memories on two sides of the server;
a connection bracket includes:
a fixation device connecting the server to a bottom of the connection bracket; and
a recess formed at a center of a top of the connection bracket and having an accommodation space; and
a heat sink including:
heat dissipation fins on two sides of the heat sink; and
a bottom component, a structure of the bottom component enabling the bottom component to be embedded in the recess of the connection bracket to form a detachable connection with the connection bracket, and the bottom component being configured to rotate around a center of the recess in the accommodation space of the recess to change a positional relationship between the heat dissipation fins and the memories to be a first positional relationship or a second positional relationship;
wherein:
in the first positional relationship, the memories are located right below the heat dissipation fins; and
in the second positional relationship, a space below the heat dissipation fins is empty and a space right above the memories is empty.

13. The server heat-dissipation system according to claim 12, wherein:
the recess includes a cylindrical recess; and
the cylindrical recess has a cylindrical space configured to form an embedded fit with a cylindrical component of the bottom component of the heat sink.

14. The server heat-dissipation system according to claim 13, wherein:
the recess further includes fan-shaped columnar recesses that are spaced apart circumferentially along a periphery of the cylindrical recess; and
each of the fan-shaped columnar recess has a fan-shaped columnar space configured to accommodate a fan-shaped columnar component of the bottom component of the heat sink.

15. The server heat-dissipation system according to claim 14, wherein:
the connection bracket further includes fan-shaped columnar hollow parts that are spaced apart circumferentially along the periphery of the cylindrical recess; and
each of the fan-shaped columnar hollow parts forms a fan-shaped columnar gap with a bottom surface of the connection bracket, the fan-shaped columnar gap being configured to accommodate the fan-shaped columnar component of the bottom component of the heat sink.

16. The server heat-dissipation system according to claim 14, wherein:
the connection bracket further includes a cutoff planar part disposed between one fan-shaped columnar recess of the fan-shaped columnar recesses and one fan-shaped columnar hollow part of the fan-shaped columnar hollow parts;
the cutoff planar part is a fan-shaped columnar solid part and configured to separate a space between the fan-shaped columnar space of the one fan-shaped columnar recess and the fan-shaped columnar gap of the one fan-shaped columnar hollow part; and
the cutoff planar part is configured to prevent the bottom component of the heat sink from continuing to rotate after the bottom component of the heat sink is rotated to an angle in the accommodation space around the center of the recess.

17. The server heat-dissipation system according to claim 12, wherein:
the connection bracket further includes a first threaded hole and a second threaded hole disposed on two sides of the recess; and
the connection bracket is fixedly connected to the heat sink through the first threaded hole and the second threaded hole.

18. The server heat-dissipation system according to claim 12, wherein the connection bracket further includes a thermal conductive lubrication material configured to be filled in a remaining space of the accommodation space after the recess contacts the bottom component of the heat sink.

19. The server heat-dissipation system according to claim 12, wherein the bottom component includes a cylindrical component configured to be embedded in a cylindrical space of the recess of the connection bracket.

20. The server heat-dissipation system according to claim 19, wherein:
the bottom component further includes fan-shaped columnar components that are spaced apart circumferentially along a periphery of the cylindrical component; and
the fan-shaped columnar components are configured to be embedded in fan-shaped columnar spaces of fan-shaped columnar recesses of the connection bracket.
